(19) United States
(12) Patent Application Publication
(10) Pub. No.: US 2006/0157866 A1
(43) Pub. Date: Jul. 20, 2006

(54) Signal redistribution using bridge layer for multichip module

(76) Inventors: Thoai Thai Le, Cary, NC (US); Jong-Hoon Oh, Chapel Hill, NC (US)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/039,293

(22) Filed: Jan. 20, 2005

(51) Int. Cl. H01L 21/50; H01L 21/44; H01L 23/52

(52) U.S. Cl. 257/777; 438/617; 438/107; 257/E21.499

(57) ABSTRACT

A multichip module (MCM) comprises a first integrated circuit and a second integrated circuit, a bridge layer over at least a portion of the second integrated circuit, one or more first interconnects conductively coupled between one or more contact areas of the first integrated circuit and one or more first contact areas of the bridge layer, and one or more second interconnects conductively coupled between one or more second contact areas of the bridge layer and one or more contact areas for a package. At least a portion of the first integrated circuit is positioned over a portion of the second integrated circuit. The bridge layer for one or more embodiments may define one or more signal paths between one or more first contact areas of the bridge layer and one or more second contact areas of the bridge layer. The bridge layer for one or more embodiments may define one or more signal paths between one or more first contact areas of the bridge layer and input/output (I/O) circuitry of the second integrated circuit and may define one or more signal paths between the I/O circuitry of the second integrated circuit and one or more second contact areas of the bridge layer to transmit signals out of the package from the first integrated circuit and/or to receive signals for the first integrated circuit from outside the package.

### BACKGROUND

1. Field of the Invention

The invention generally relates to multichip modules (MCMs).

2. Description of the Related Art

Many electronic applications require a set of integrated circuit (IC) chips that are packaged together, for example, on a common printed circuit (PC) board. For example, many applications call for a processor and some type of memory or different types of memory, such as dynamic random access memory (DRAM) and non-volatile (e.g., flash) memory, to be included on the same PC board. If economies of scale dictate, it is sometimes more cost effective to package these integrated circuits together into a single multichip module (MCM), that allows tight integration of the devices and occupies less PC board space.

FIGS. 1 and 2 illustrate a prior art MCM 100 prior to package encapsulation. MCM 100 comprises an upper integrated circuit (IC) 110 positioned over a lower integrated circuit 120 which is positioned over a package substrate 140. Because the size of upper integrated circuit 110 is smaller than that of lower integrated circuit 120, using a wire bonding technique to form MCM 100 requires lengthy bond wires, such as a bond wire 150 for example, to span from upper integrated circuit 110 beyond lower integrated circuit 120 to package substrate 140. Such lengthy bond wires, however, may limit how thin the package for MCM 100 may be formed while maintaining stability of the bond wires.

Accordingly, what is needed is techniques and apparatus for improved MCM packaging.

### SUMMARY

One or more disclosed methods for packaging a first integrated circuit and a second integrated circuit comprise positioning at least a portion of the first integrated circuit over a portion of the second integrated circuit, coupling one or more contact areas of the first integrated circuit to one or more first contact areas of a bridge layer over at least a portion of the second integrated circuit, and coupling one or more second contact areas of the bridge layer to one or more contact areas for a package. The bridge layer defines one or more signal paths between the one or more first contact areas of the bridge layer and the one or more second contact areas of the bridge layer.

One or more disclosed methods for packaging a first integrated circuit and a second integrated circuit comprise positioning at least a portion of the first integrated circuit over a portion of the second integrated circuit, coupling one or more contact areas of the first integrated circuit to one or more first contact areas of a bridge layer over at least a portion of the second integrated circuit, and coupling one or more second contact areas of the bridge layer to one or more contact areas for a package. The one or more first contact areas are conductively coupled to input/output (I/O) circuitry of the second integrated circuit. The one or more second contact areas are conductively coupled to the I/O circuitry of the second integrated circuit to transmit signals out of the package from the first integrated circuit and/or to receive signals for the first integrated circuit from outside the package.

One or more disclosed multichip modules (MCMs) comprise a first integrated circuit and a second integrated circuit, a bridge layer over at least a portion of the second integrated circuit, one or more first interconnects conductively coupled between one or more contact areas of the first integrated circuit and one or more first contact areas of the bridge layer, and one or more second interconnects conductively coupled between one or more second contact areas of the bridge layer and one or more contact areas for a package. At least a portion of the first integrated circuit is positioned over a portion of the second integrated circuit. The bridge layer defines one or more signal paths between the one or more first contact areas of the bridge layer and the one or more second contact areas of the bridge layer.

One or more disclosed multichip modules (MCMs) comprise a first integrated circuit and a second integrated circuit, a bridge layer over at least a portion of the second integrated circuit, one or more first interconnects conductively coupled between one or more contact areas of the first integrated circuit and one or more first contact areas of the bridge layer, and one or more second interconnects conductively coupled between one or more second contact areas of the bridge layer and one or more contact areas for a package. At least a portion of the first integrated circuit is positioned over a portion of the second integrated circuit. The bridge layer defines one or more signal paths between the one or more first contact areas of the bridge layer and input/output (I/O) circuitry of the second integrated circuit and defines one or more signal paths between the I/O circuitry of the second integrated circuit and the one or more second contact areas of the bridge layer to transmit signals out of the package from the first integrated circuit and/or to receive signals for the first integrated circuit from outside the package.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a plan view of a prior art multichip module (MCM) prior to package encapsulation;

FIG. 2 illustrates a partial side, cross-sectional view of the prior art MCM of FIG. 1;

FIG. 3 illustrates, for one or more embodiments, a plan view of a MCM, prior to package encapsulation, having a bridge layer for signal redistribution;

FIG. 4 illustrates, for one or more embodiments, a partial side, cross-sectional view of the MCM of FIG. 3;

FIG. 5 illustrates, for one or more embodiments, a partial side, cross-sectional view of another MCM, prior to package encapsulation, having a bridge layer for signal redistribution;

FIG. 6 illustrates, for one or more embodiments, an exploded, perspective view of another MCM, prior to package encapsulation, having a bridge layer for signal redistribution; and

FIG. 7 illustrates, for one or more embodiments, a flow diagram for forming a MCM using a bridge layer for signal redistribution.

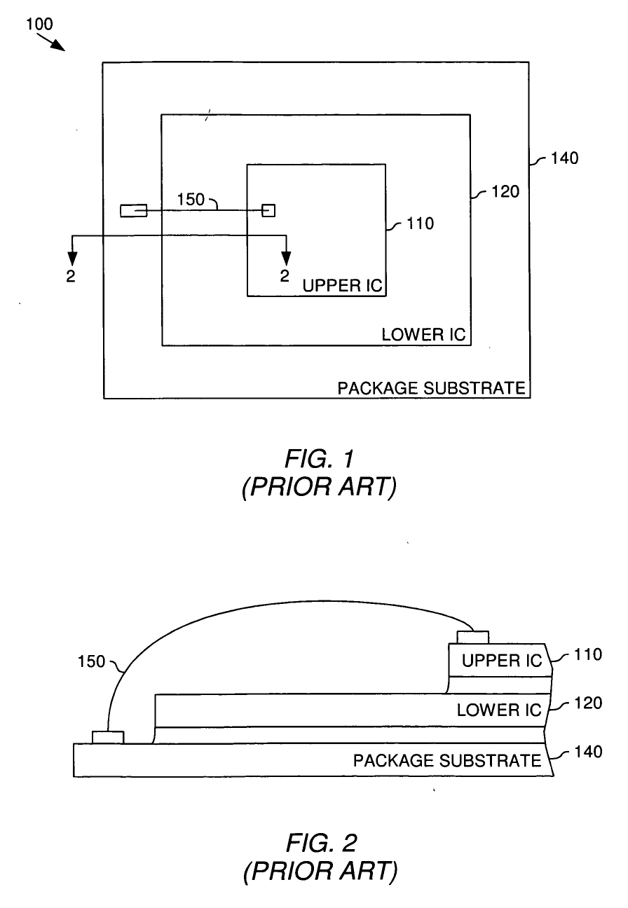

### DETAILED DESCRIPTION

Embodiments of the invention generally provide signal redistribution using a bridge layer for a multichip module (MCM) to help provide more stable input/output (I/O) interconnections for one or more integrated circuits of the MCM. For one or more embodiments, shorter interconnects may be used to conductively couple an upper integrated circuit to a bridge layer over a lower integrated circuit and to conductively couple the bridge layer to one or more contact areas for a package that is to house the upper and lower integrated circuits. In this manner, lengthy interconnects, such as lengthy bond wires for example, may be avoided, helping to allow the package to be made thinner while maintaining stability of the interconnects.

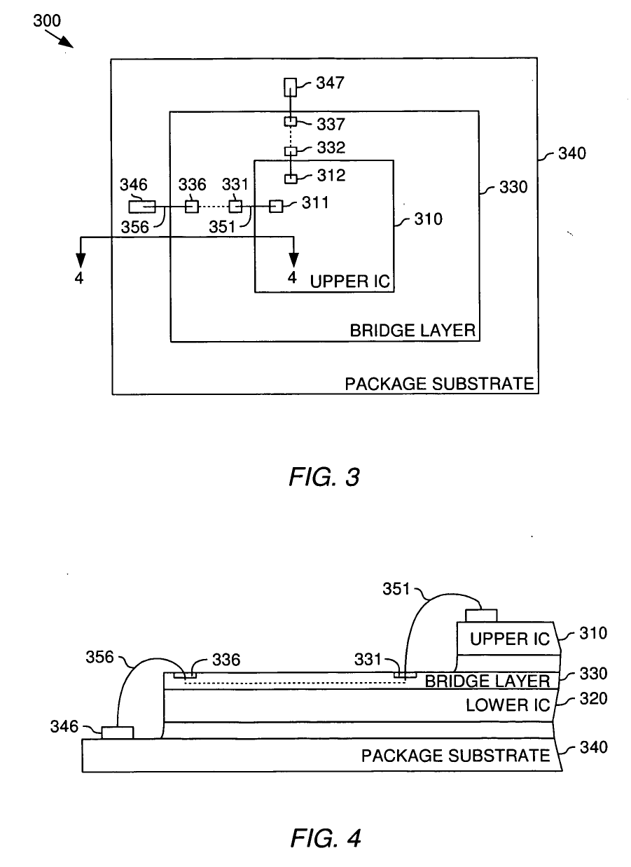

FIGS. 3 and 4 illustrate for one or more embodiments a multichip module (MCM) 300 prior to package encapsulation. MCM 300 comprises an upper integrated circuit 310, a lower integrated circuit 320, a bridge layer 330 over at least a portion of lower integrated circuit 320, and a package substrate 340.

Upper and lower integrated circuits 310 and 320 may comprise any suitable circuitry. As an example, upper integrated circuit 310 may comprise dynamic random access memory (DRAM) circuitry, and lower integrated circuit 320 may comprise flash memory or electrically erasable programmable read only memory (EEPROM) circuitry. As another example, upper integrated circuit 310 may comprise any suitable memory circuitry, and lower integrated circuit 320 may comprise processor circuitry. As yet another example, upper integrated circuit 310 may comprise any suitable circuitry using complementary metal oxide semiconductor (CMOS) technology, and lower integrated circuit 320 may comprise any suitable circuitry using bipolar technology. Upper and lower integrated circuits 310 and 320 for one or more embodiments may comprise circuitry to form MCM 300 as a system in a package (SiP).

At least a portion of upper integrated circuit 310 is positioned over a portion of lower integrated circuit 320, leaving at least a portion of bridge layer 330 having contact areas exposed. Upper integrated circuit 310 for one or more embodiments, as illustrated in FIG. 3, may have a length and/or width that is smaller than those of lower integrated circuit 320. At least a portion of lower integrated circuit 320 is positioned over a portion of package substrate 340, leaving at least a portion of package substrate 340 having one or more contact areas exposed.

Bridge layer 330 defines one or more signal paths between one or more first contact areas of bridge layer 330, such as bonding pads 331 and 332 for example, and one or more second contact areas of bridge layer 330, such as bonding pads 336 and 337 for example.

One or more first interconnects are conductively coupled between one or more contact areas of upper integrated circuit 310 and the one or more first contact areas of bridge layer 330. Upper integrated circuit 310 for one or more embodiments may have one or more contact areas, such as bonding pads 311 and 312 for example, at a surface of upper integrated circuit 310 facing away from lower integrated circuit 320. The first interconnect(s) for one or more embodiments may comprise, for example, bond wire(s). As illustrated in FIGS. 3 and 4, a bond wire 351, for example, may be used to interconnect bonding pads 311 and 331.

One or more second interconnects are conductively coupled between the one or more second contact areas of bridge layer 330 and one or more contact areas of package substrate 340, such as bonding pads 346 and 347 for example. The second interconnect(s) for one or more embodiments may comprise, for example, bond wire(s). As illustrated in FIGS. 3 and 4, a bond wire 356, for example, may be used to interconnect bonding pads 336 and 346.

Bridge layer 330 may define a signal path between first and second contact areas at any suitable locations on bridge layer 330 to help provide a signal path between a contact area at any suitable location on upper integrated circuit 310 and a contact area at any suitable location on package substrate 340. In this manner, upper integrated circuit 310 for one or more embodiments may be designed with reduced concern for where input/output (I/O) interconnections for upper integrated circuit 310 are to be made with package substrate 340. Bridge layer 330 for one or more embodiments, as illustrated in FIGS. 3 and 4, may help provide a signal path between a contact area located on upper integrated circuit 310 closer to one side of package substrate 340 and a contact area located on package substrate 340 along the same side of package substrate 340. Bridge layer 330 for one or more embodiments may help provide a signal path between a contact area located on upper integrated circuit 310 closer to one side of package substrate 340 and a contact area located on package substrate 340 along a different side of package substrate 340.

Bridge layer 330 for one or more embodiments may also define one or more signal paths between any suitable circuitry at any suitable location(s) in lower integrated circuit 320 and one or more contact areas at any suitable location(s) on bridge layer 330. Such a contact area for one or more embodiments may be conductively coupled by an interconnect, such as a bond wire for example, to a contact area on package substrate 340 to provide an input/output (I/O) interconnection for lower integrated circuit 320 to package substrate 340. Such a contact area for one or more embodiments may be conductively coupled by an interconnect, such as a bond wire for example, to a contact area on upper integrated circuit 310 to help provide an input/output (I/O) interconnection between upper integrated circuit 310 and lower integrated circuit 320.

Bridge layer 330 for one or more embodiments may define one or more signal paths for both upper integrated circuit 310 and lower integrated circuit 320 to share one or more package input/output (I/O) interconnections. In this manner, MCM 300 for one or more embodiments may be designed with a reduced number of I/O interconnections. For example, the MCM 300 may include different types of memory devices (e.g., DRAM and flash memory), that share a common number of address, data, or command lines routed from an external pin to both devices via the bridge layer 330.

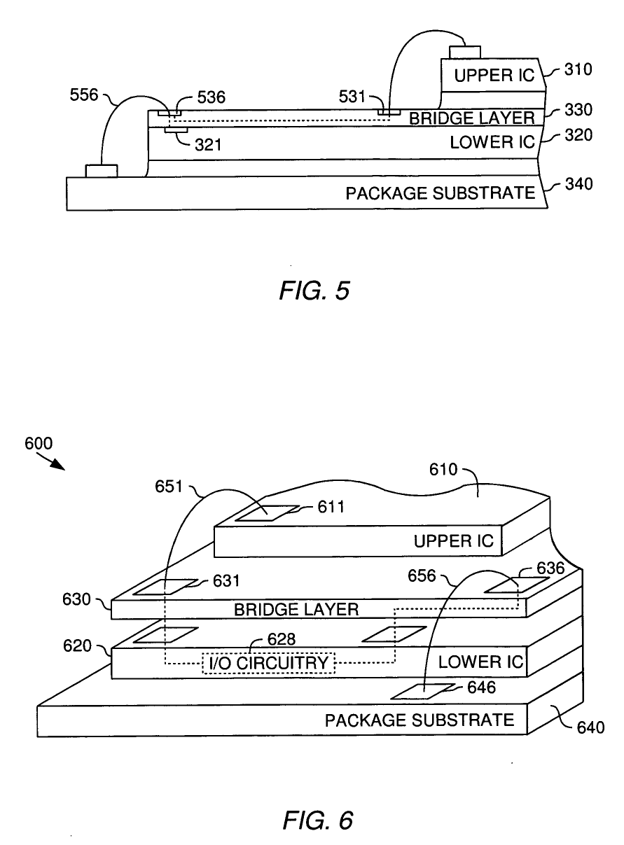

Bridge layer 330 for one or more embodiments, as illustrated in FIG. 5, may define a signal path between first and second contact areas on bridge layer 330, such as bonding pads 531 and 536 for example, and between the second contact area on bridge layer 330 and circuitry of lower integrated circuit 320, through a pad 321 for example, to provide an I/O interconnection for both upper integrated circuit 310 and lower integrated circuit 320 to package substrate 340 using the same interconnect, such as a wire bond 556 for example, conductively coupled between the second contact area of bridge layer 330 and package substrate 340. Although illustrated as defining the second contact area over pad 321, bridge layer 330 for one or more embodiments may define the signal path between the second contact area on bridge layer 330 and any suitable circuitry at any suitable location in lower integrated circuit 320.

Bridge layer 330 may be formed over lower integrated circuit 320 in any suitable manner to define any suitable one or more signal paths in any suitable manner. Bridge layer 330 for one or more embodiments may be formed as a plurality of sublayers to define signal paths that cross over one another. Bridge layer 330 for one or more embodiments may be formed as one or more additional metal layers over lower integrated circuit 320.

FIG. 6 illustrates for one or more embodiments a multichip module (MCM) 600 prior to package encapsulation. MCM 600 comprises an upper integrated circuit 610, a lower integrated circuit 620, a bridge layer 630 over at least a portion of lower integrated circuit 620, and a package substrate 640. Upper integrated circuit 610, lower integrated circuit 620, bridge layer 630, and package substrate 640 generally correspond to upper integrated circuit 310, lower integrated circuit 320, bridge layer 330, and package substrate 340 of FIGS. 3 and 4.

Bridge layer 630 of FIG. 6 defines one or more signal paths between one or more first contact areas of bridge layer 630, such as a bonding pad 631 for example, and input/output (I/O) circuitry 628 of lower integrated circuit 620 and defines one or more signal paths between I/O circuitry 628 and one or more second contact areas of bridge layer 630, such as a bonding pad 636 for example.

One or more first interconnects, such as a bond wire 651 for example, are conductively coupled between one or more contact areas of upper integrated circuit 610, such as a bonding pad 611 for example, and the one or more first contact areas of bridge layer 630. One or more second interconnects, such as a bond wire 656 for example, are conductively coupled between the one or more second contact areas of bridge layer 630 and one or more contact areas of package substrate 640, such as a bonding pad 646 for example.

By interconnecting upper integrated circuit 610 to package substrate 640 in this manner, upper integrated circuit 610 may then transmit signals out of the package for MCM 600 and/or receive signals from outside the package for MCM 600 using I/O circuitry 628 of lower integrated circuit 620. I/O circuitry 628 for one or more embodiments may comprise any suitable circuitry to switch I/O signals for upper integrated circuit 610. I/O circuitry 628 for one or more embodiments may comprise any suitable circuitry to serve as the I/O interface for upper integrated circuit 610. Interconnecting upper integrated circuit 610 to I/O circuitry 628 of lower integrated circuit 620 for one or more embodiments may also help provide a faster signal connection between upper integrated circuit 610 and lower integrated circuit 620 and help provide a stable loading on package I/O interconnections for lower integrated circuit 620.

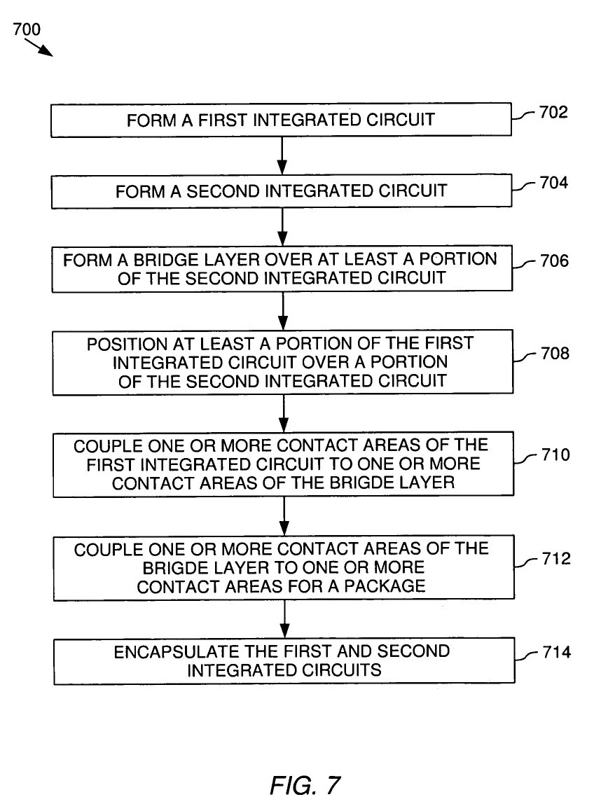

FIG. 7 illustrates, for one or more embodiments, a flow diagram 700 for forming a multichip module (MCM) using a bridge layer for signal redistribution. Flow diagram 700 may be used, for example, to form MCM 300 of FIG. 3 or MCM 600 of FIG. 6.

As illustrated in FIG. 7, a first integrated circuit is formed for block 702 and a second integrated circuit is formed for block 704. The first and second integrated circuits may be formed in any suitable manner to comprise any suitable circuitry. The first integrated circuit generally corresponds to upper integrated circuit 310 of FIGS. 3-5 or upper integrated circuit 610 of FIG. 6, and the second integrated circuit generally corresponds to lower integrated circuit 320 of FIGS. 3-5 or lower integrated circuit 620 of FIG. 6.

For block 706, a bridge layer is formed over at least a portion of the second integrated circuit. The bridge layer may be formed in any suitable manner over any suitable one or more portions or all of the second integrated circuit. For block 708, at least a portion of the first integrated circuit is positioned over a portion of the second integrated circuit. The first integrated circuit for one or more embodiments may be positioned directly over the bridge layer and coupled to the bridge layer in any suitable manner. For one or more other embodiments where the bridge layer is formed over only one or more portions of the second integrated circuit, the first integrated circuit for one or more embodiments may be positioned directly over the second integrated circuit and coupled to the second integrated circuit in any suitable manner.

For block 710, one or more contact areas of the first integrated circuit are coupled to one or more contact areas of the bridge layer. For block 712, one or more contact areas of the bridge layer are coupled to one or more contact areas for a package.

Such contact areas may be defined in any suitable manner, such as in the form of a bonding pad for example. The one or more contact areas for a package for one or more embodiments may be defined on a package substrate over which the second integrated circuit may be positioned. The package substrate may be formed of any suitable material. The one or more contact areas for a package for one or more other embodiments may be defined on a package lead frame.

Contact areas may be coupled to one another in any suitable manner using any suitable interconnect, such as a bond wire for example. For one or more embodiments, any suitable wire bonding technique may be used.

For block 714, the first and second integrated circuits are encapsulated. The first and second integrated circuits may be encapsulated in any suitable manner using any suitable material.

Operations for blocks 702, 704, 706, 708, 710, 712, and/or 714 may be performed in any suitable order and may or may not be performed so as to overlap in time the performance of any suitable operation with any other suitable operation. As one example, the first integrated circuit may be formed for block 702 after the second integrated circuit is formed for block 704.

As used in this detailed description, directional terms such as, for example, upper, lower, and over are used for convenience to describe a multichip module (MCM) relative to one frame of reference regardless of how the MCM may be oriented in space.

Embodiments of the invention generally providing signal redistribution using a bridge layer for a multichip module (MCM) to help provide more stable input/output (I/O) interconnections for one or more integrated circuits of the MCM have therefore been described. While the foregoing is directed to embodiments of the present invention, other and further embodiments of the invention may be devised without departing from the basic scope thereof, and the scope thereof is determined by the claims that follow.

What is claimed is:

1. A method for packaging a first integrated circuit and a second integrated circuit comprising:
positioning at least a portion of the first integrated circuit over a portion of the second integrated circuit;
coupling one or more contact areas of the first integrated circuit to one or more first contact areas of a bridge layer over at least a portion of the second integrated circuit, the bridge layer defining one or more signal paths between the one or more first contact areas of the bridge layer and one or more second contact areas of the bridge layer; and
coupling the one or more second contact areas of the bridge layer to one or more contact areas for a package.

2. The method of claim 1, wherein coupling one or more second contact areas of the bridge layer to one or more contact areas for a package comprises coupling one or more second contact areas conductively coupled to circuitry of the second integrated circuit to one or more contact areas for a package.

3. The method of claim 1, wherein coupling one or more contact areas of the first integrated circuit to one or more first contact areas of the bridge layer comprises coupling one or more contact areas at a surface of the first integrated circuit facing away from the second integrated circuit to one or more first contact areas of the bridge layer.

4. The method of claim 1, wherein coupling one or more contact areas of the first integrated circuit to one or more first contact areas of the bridge layer comprises using a wire bonding technique.

5. The method of claim 1, wherein coupling one or more second contact areas of the bridge layer to one or more contact areas for a package comprises using a wire bonding technique.

6. A method for packaging a first integrated circuit and a second integrated circuit comprising:
positioning at least a portion of the first integrated circuit over a portion of the second integrated circuit;
coupling one or more contact areas of the first integrated circuit to one or more first contact areas of a bridge layer over at least a portion of the second integrated circuit, the one or more first contact areas conductively coupled to input/output (I/O) circuitry of the second integrated circuit; and
coupling one or more second contact areas of the bridge layer to one or more contact areas for a package, the one or more second contact areas conductively coupled to the I/O circuitry of the second integrated circuit to transmit signals out of the package from the first integrated circuit and/or to receive signals for the first integrated circuit from outside the package.

7. The method of claim 6, wherein coupling one or more contact areas of the first integrated circuit to one or more first contact areas of the bridge layer comprises coupling one or more contact areas at a surface of the first integrated circuit facing away from the second integrated circuit to one or more first contact areas of the bridge layer.

8. The method of claim 6, wherein coupling one or more contact areas of the first integrated circuit to one or more first contact areas of the bridge layer comprises using a wire bonding technique.

9. The method of claim 6, wherein coupling one or more second contact areas of the bridge layer to one or more contact areas for a package comprise using a wire bonding technique.

10. A multichip module (MCM) comprising:
a first integrated circuit and a second integrated circuit, wherein at least a portion of the first integrated circuit is positioned over a portion of the second integrated circuit;
a bridge layer over at least a portion of the second integrated circuit, the bridge layer defining one or more signal paths between one or more first contact areas of the bridge layer and one or more second contact areas of the bridge layer;
one or more first interconnects conductively coupled between one or more contact areas of the first integrated circuit and the one or more first contact areas of the bridge layer; and
one or more second interconnects conductively coupled between the one or more second contact areas of the bridge layer and one or more contact areas for a package.

11. The multichip module (MCM) of claim 10, wherein the bridge layer defines one or more signal paths between one or more second contact areas of the bridge layer and circuitry of the second integrated circuit.

12. The multichip module (MCM) of claim 10, wherein one or more first interconnects are conductively coupled between one or more contact areas at a surface of the first integrated circuit facing away from the second integrated circuit and one or more first contact areas of the bridge layer.

13. The multichip module (MCM) of claim 10, wherein one or more first interconnects comprise a bond wire.

14. The multichip module (MCM) of claim 10, wherein one or more second interconnects comprise a bond wire.

15. The multichip module (MCM) of claim 10, comprising a package substrate, wherein the second integrated circuit is positioned over the package substrate and wherein one or more contact areas for the package are defined on the package substrate.

16. The multichip module (MCM) of claim 10, wherein the first integrated circuit comprises dynamic random access memory and the second integrated circuit comprises flash memory.

17. A multichip module (MCM) comprising:
a first integrated circuit and a second integrated circuit, wherein at least a portion of the first integrated circuit is positioned over a portion of the second integrated circuit;
a bridge layer over at least a portion of the second integrated circuit;
one or more first interconnects conductively coupled between one or more contact areas of the first integrated circuit and one or more first contact areas of the bridge layer; and
one or more second interconnects conductively coupled between one or more second contact areas of the bridge layer and one or more contact areas for a package,
wherein the bridge layer defines one or more signal paths between the one or more first contact areas of the bridge layer and input/output (I/O) circuitry of the second integrated circuit and defines one or more signal paths between the I/O circuitry of the second integrated circuit and the one or more second contact areas of the bridge layer to transmit signals out of the package from the first integrated circuit and/or to receive signals for the first integrated circuit from outside the package.

18. The multichip module (MCM) of claim 17, wherein one or more first interconnects are conductively coupled between one or more contact areas at a surface of the first integrated circuit facing away from the second integrated circuit and one or more first contact areas of the bridge layer.

19. The multichip module (MCM) of claim 17, wherein one or more first interconnects comprise a bond wire.

20. The multichip module (MCM) of claim 17, wherein one or more second interconnects comprise a bond wire.

21. The multichip module (MCM) of claim 17, comprising a package substrate, wherein the second integrated circuit is positioned over the package substrate and wherein one or more contact areas for the package are defined on the package substrate.

22. The multichip module (MCM) of claim 17, wherein the first integrated circuit comprises dynamic random access memory and the second integrated circuit comprises flash memory.
